(19) United States
(12) Patent Application Publication
(10) Pub. No.: US 2013/0146140 A1
(43) Pub. Date: Jun. 13, 2013

(54) DYE-SENSITIZED SOLAR CELL

(71) Applicants: Nam-Choul Yang, Yongin-si (KR); Sung-Su Kim, Yongin-si (KR); Hyun-Chul Kim, Yongin-si (KR)

(72) Inventors: Nam-Choul Yang, Yongin-si (KR); Sung-Su Kim, Yongin-si (KR); Hyun-Chul Kim, Yongin-si (KR)

(73) Assignee: SAMSUNG SDI CO., LTD., Yongin-si (KR)

(21) Appl. No.: 13/460,314

(22) Filed: Apr. 30, 2012

(30) Foreign Application Priority Data
Dec. 7, 2011 (KR) 10-2011-0130472

(51) Int. Cl. H01L 31/0203; H01L 31/0232; H01L 31/0256

(52) U.S. Cl. 136/259

(57) ABSTRACT

In one aspect, a dye-sensitized solar cell is provided including: first and second substrates disposed to face each other; and a sealing material disposed between the first and second substrates and defining at least one photoelectric cell that performs photoelectric conversion, wherein the photoelectric cell includes: a first region; and a second region spatially connected to the first region and having higher transparency than the first region, wherein the first region performs photoelectric conversion of light incident through the first region and light incident through the second region.

### CROSS-REFERENCE TO RELATED APPLICATION

This application claims the benefit of Korean Patent Application No. 10-2011-0130472, filed on Dec. 7, 2011, in the Korean Intellectual Property Office, the disclosure of which is incorporated herein in its entirety by reference.

### BACKGROUND

1. Field

One or more embodiments relate to dye-sensitized solar cells.

2. Description of the Related Technology

Photoelectric conversion devices which convert light energy to electric energy and solar cells using sun light to generate electric energy have drawn much attention as energy sources that can replace fossil fuel.

Solar cells using various driving principles have been studied, and silicon or crystalline solar cells having a wafer shape and using a p-n junction of semiconductor have been mostly manufactured, but the manufacturing costs thereof are high due to the necessity of forming and handling semiconductor materials having high purity.

Unlike silicon solar cells, dye-sensitized solar cells are proposed to be next-generation solar cells since they mainly include a dye molecule for generating excited electrons by receiving light having a wavelength in the visible spectrum, a semiconductor material for receiving the excited electrons, and an electrolyte reacting with electrons retrieved from an external circuit. Also, the dye-sensitized solar cells may have a photoelectric conversion efficiency that is higher when compared to conventional solar cells.

### SUMMARY

One or more embodiments include dye-sensitized solar cells having improved light utilization rate.

Additional aspects will be set forth in part in the description which follows and, in part, will be apparent from the description, or may be learned by practice of the presented embodiments.

According to one or more embodiments, a dye-sensitized solar cell includes: first and second substrates disposed to face each other; and a sealing material disposed between the first and second substrates and defining at least one photoelectric cell that performs photoelectric conversion, wherein the photoelectric cell includes: a first region; and a second region connected to the first region and having higher transparency than the first region, wherein the first region performs photoelectric conversion using incident light through the first region and incident light through the second region. In certain embodiments, the plane of the first substrate may be substantially parallel to the plane of the second substrate. In certain embodiments, the plane of the first substrate may be parallel to the plane of the second substrate. In certain embodiments, the first substrate may be substantially overlapping to the second substrate. In certain embodiments, the first substrate may be fully overlapping and within the dimensions of the second substrate. In certain embodiments, the second substrate may be fully overlapping and within the dimensions of the first substrate. In certain embodiments, the first substrate may have the same shape as the second substrate. In certain embodiments, the first substrate may have a different shape as the second substrate. In certain embodiments, the first substrate may have the same dimensions as the second substrate. In certain embodiments, the first substrate may have different dimensions as the second substrate. In certain embodiments, the first and second substrates each have an approximate rectangular shape. In certain embodiments, the first and second substrates each have an approximate square shape.

In certain embodiments, the first region may include: first and second electrodes respectively disposed on inner sides of the first and second substrates; a semiconductor layer disposed on the first electrode and adsorbing dye molecules; a scattering layer disposed on the semiconductor layer and scattering light that passed through the semiconductor layer toward the semiconductor layer; and an electrolyte disposed between the scattering layer and the second electrode.

In certain embodiments, the first region may include a catalyst layer disposed on the second electrode.

In certain embodiments, the catalyst layer may reflect light that passed through the scattering layer.

In certain embodiments, the second region may include an electrolyte disposed between the first and second substrates.

In certain embodiments, the second region may include: a first transparent electrode disposed between the first substrate and the electrolyte; and a second transparent electrode disposed between the second substrate and the electrolyte.

In certain embodiments, the first region may be disposed at two sides of the second region.

In certain embodiments, the first region and the second region may be spatially connected to each other.

In certain embodiments, the dye-sensitized solar cell further comprises an electrolyte wherein the first region and the second region may be fluidally connected to each other through the electrolyte.

According to one or more embodiments, a dye-sensitized solar cell includes: first and second substrates disposed to face each other; and a sealing member disposed between the first and second substrates to define at least one photoelectric cell that performs photoelectric conversion, and sealing an electrolyte accommodated in the at least one photoelectric cell, wherein the at least one photoelectric cell includes: a first region including first and second electrodes respectively disposed on inner sides of the first and second substrates, and a semiconductor layer disposed on the first electrode and adsorbing dye molecules; and a second region connected to the first region and having higher transparency than the first region, wherein the first region performs photoelectric conversion using incident light through the first region and incident light through the second region. In certain embodiments, the plane of the first substrate may be substantially parallel to the plane of the second substrate. In certain embodiments, the plane of the first substrate may be parallel to the plane of the second substrate. In certain embodiments, the first substrate may be substantially overlapping to the second substrate. In certain embodiments, the first substrate may be fully overlapping and within the dimensions of the second substrate. In certain embodiments, the second substrate may be fully overlapping and within the dimensions of the first substrate. In certain embodiments, the first substrate may have the same shape as the second substrate. In certain embodiments, the first substrate may have a different shape as the second substrate. In certain embodiments, the first substrate may have the same dimensions as the second substrate. In certain embodiments, the first substrate may have different dimensions as the second substrate. In certain embodiments, the first and second substrates each have an approximate rectangular shape. In certain embodiments, the first and second substrates each have an approximate square shape.

In certain embodiments, the first region may further include a scattering layer disposed on the semiconductor layer and scattering light that passed through the semiconductor layer toward the semiconductor layer.

In certain embodiments, the second region may not include the semiconductor layer and the scattering layer.

In certain embodiments, the second region may include the electrolyte disposed between the first substrate and the second substrate.

In certain embodiments, the second region may include: the first electrode disposed between the first substrate and the electrolyte; and the second electrode disposed between the second substrate and the electrolyte.

In certain embodiments, the first region may further include a catalyst layer disposed on the second electrode.

In certain embodiments, the catalyst layer may include a metal thin film that is configured to reflect light that passes through the scattering layer.

In certain embodiments, the first region and the second region may be spatially connected to each other.

In certain embodiments, the first region may be disposed at two sides of the second region.

### BRIEF DESCRIPTION OF THE DRAWINGS

These and/or other aspects will become apparent and more readily appreciated from the following description of the embodiments, taken in conjunction with the accompanying drawings of which:

FIG. 1 is a top view of a dye-sensitized solar cell according to an aspect of the present embodiments;

FIG. 2 is a schematic exploded perspective view of the dye-sensitized solar cell of FIG. 1;

FIG. 3 is a lateral cross-sectional view taken along a line of FIG. 1;

FIG. 4 is a lateral cross-sectional view schematically illustrating a dye-sensitized solar cell according to another aspect of the present embodiments;

FIG. 5 is a lateral cross-sectional view of a dye-sensitized solar cell according to an aspect of the present embodiments, wherein a plurality of cells are electrically connected to each other;

FIG. 6 is a lateral cross-sectional view of a dye-sensitized solar cell according to another aspect of the present embodiments, wherein a plurality of cells are electrically connected to each other; and

FIG. 7 is a graph of relative power to effective transmittance for comparing a dye-sensitized solar cell according to certain embodiments and a dye-sensitized solar cell according to a comparative example.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description.

The terminology used herein is for the purpose of describing particular embodiments only and is not intended to be limiting of the present embodiments. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. While such terms as “first,” “second,” etc., may be used to describe various components, such components must not be limited to the above terms. The above terms are used only to distinguish one component from another. As used herein, the term “and/or” includes any and all combinations of one or more of the associated listed items.

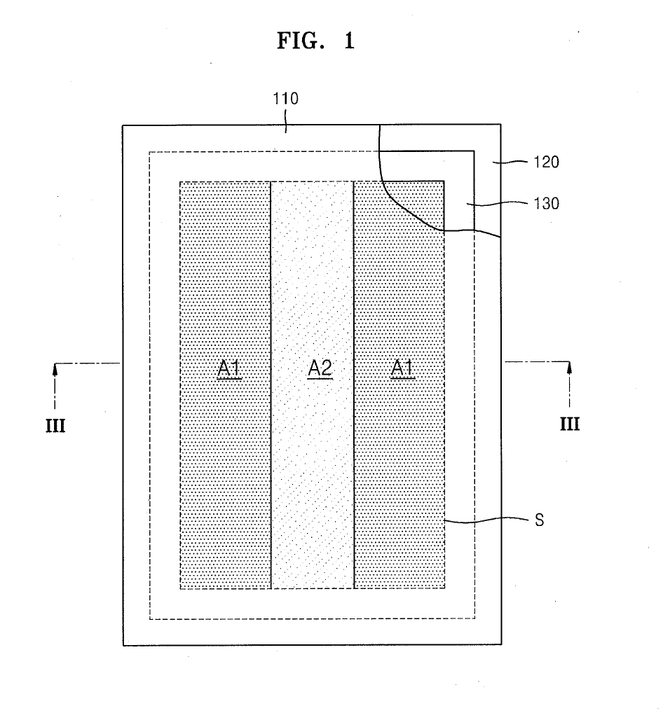

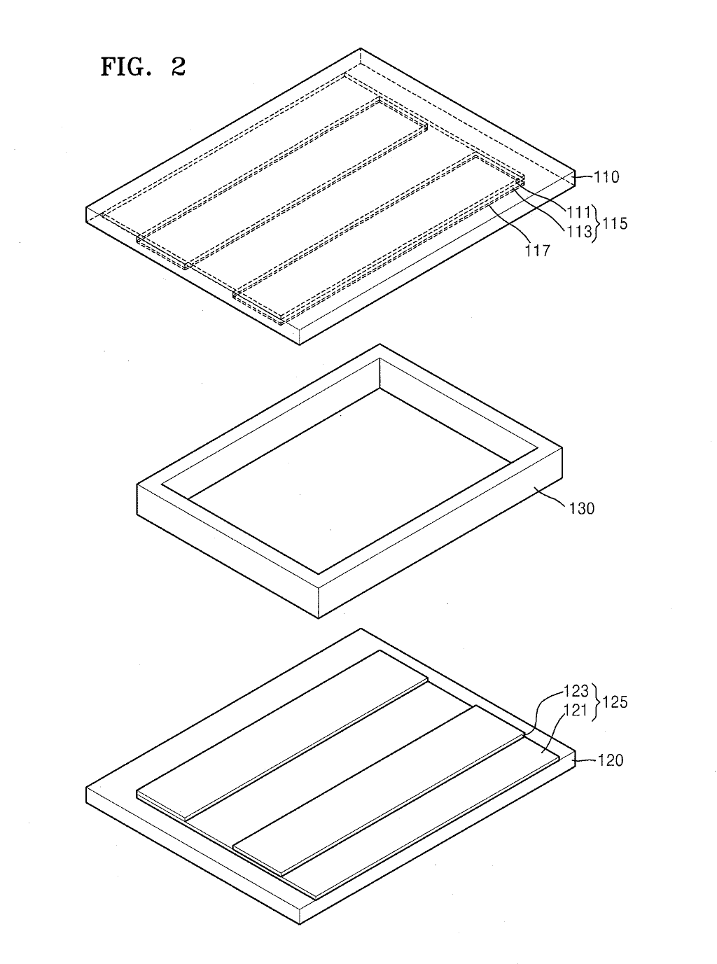

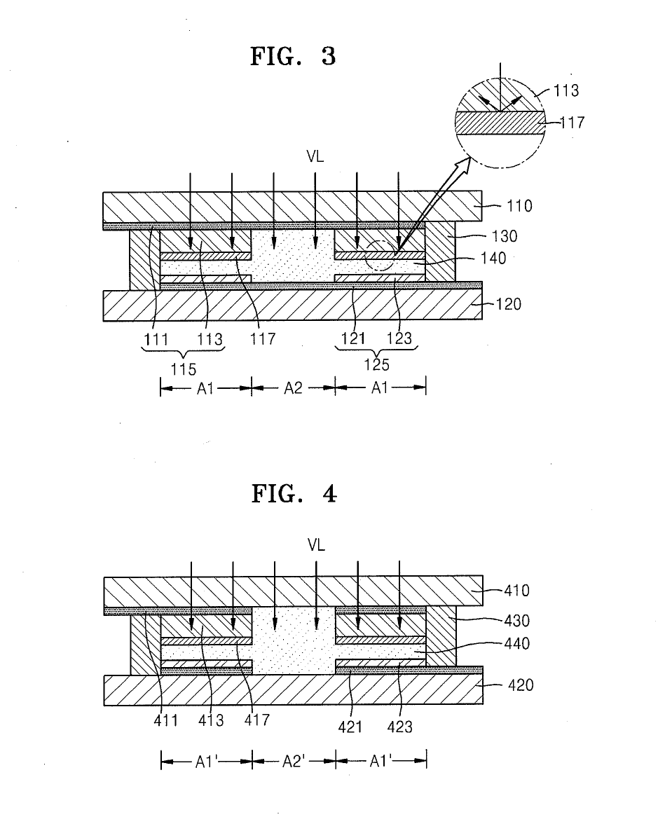

FIG. 1 is a top view of a dye-sensitized solar cell according to an aspect of the present embodiments, FIG. 2 is a schematic exploded perspective view of the dye-sensitized solar cell of FIG. 1, and FIG. 3 is a lateral cross-sectional view taken along a line of FIG. 1.

Referring to FIGS. 1 through 3, the dye-sensitized solar cell includes a photoelectric cell S where photoelectric conversion is generated, wherein the photoelectric cell S is defined by first and second substrates 110 and 120 disposed to face each other and a sealing material 130, and includes a first region A1 and a second region A2.

In certain embodiments, the first and second substrates 110 and 120 may have an approximate rectangular shape. In certain embodiments, the first substrate 110 may be a light-receiving substrate and may include a transparent material having high light transmittance. In certain embodiments, the first substrate 110 may be formed of transparent glass, and alternatively, may be formed of flexible plastic, such as polyethylene terephthalate (PET), polycarbonate (PC), polyimide (PI), polyethylene naphthalate (PEN), or polyether sulfone (PES).

In certain embodiments, the second substrate 120 may be disposed as a counter substrate to face the first substrate 110 constituting the light-receiving substrate. In certain embodiments, the second substrate 120 may include a transparent material.

In certain embodiments, the first and second substrates 110 and 120 may adhere to each other via the sealing material 130. In certain embodiments, the sealing material 130 may be disposed between the first and second substrates 110 and 120 to define the photoelectric cell S, and prevents an electrolyte 140 accommodated in the photoelectric cell S from externally leaking.

In certain embodiments, the photoelectric cell S defined by the first and second substrates 110 and 120, and the sealing material 130 includes the first region A1 and the second region A2 spatially connected to the first region A1.

In certain embodiments, the first region A1 includes first and second functional layers 115 and 125 for performing photoelectric conversion. In certain embodiments, the first region A1 may include the first and second functional layers 115 and 125 respectively formed on the first and second substrates 110 and 120, and a scattering layer 117. In certain embodiments, the second region A2 may increase a light utilization rate of the photoelectric cell S. Unlike the first region A1, the second region A2 does not include a semiconductor layer 113, a catalyst layer 123, and the scattering layer 117.

In certain embodiments, the first region A1 may include semiconductor layer 113, catalyst layer 123, and scattering layer 117. In certain embodiments, the second region A2 may not include semiconductor layer 113, catalyst layer 123, and scattering layer 117. In certain embodiments, the first region A1 has lower transparency than the second region A2. Accordingly, the second region A2 may have relatively high transparency when compared to the first region A1. Thus, the second region A2 may have high penetration efficiency of sun light used for photoelectric conversion, and a utilization rate of light used during photoelectric conversion may be improved. Since the first and second functional layers 115 and 125 formed in the first region A1 of the dye-sensitized solar cell according to the certain embodiments not only absorb light directly incident on the first region A1 but also light incident through the second region A2 with excellent light transmittance, a light utilization rate of the entire photoelectric cell S is highly efficient.

In contrast, when only a first region is included in a photoelectric cell as a comparative example, an amount of light incident on the photoelectric cell is less than an amount of light according to the present embodiments. Accordingly, when a sun light is incident on the same area, a light utilization rate and an amount of generated power of the dye-sensitized solar cell according to the comparative example are lower than those according to the current embodiment.

Detailed structures of the first and second regions A1 and A2 will now be described in detail.

Regarding FIGS. 2 and 3, the first region A1 includes the first and second functional layers 115 and 125 for performing photoelectric conversion, and the scattering layer 117 formed on the first functional layer 115.

In certain embodiments, the first and second functional layers 115 and 125 may be respectively formed on the first and second substrates 110 and 120. In certain embodiments, the first functional layer 115 may be formed on the first substrate 110 and includes a photoelectrode 111 and the semiconductor layer 113. In certain embodiments, the second functional layer 125 may be formed on the second substrate 120 to face the first functional layer 115, and includes a counter electrode 121 and the catalyst layer 123.

The photoelectrode 111 operates as a negative electrode of the dye-sensitized solar cell, and provides a current path by collecting electrons generated according to photoelectric conversion. Light incident through the photoelectrode 111 may operate as an excitation source of dye molecules adsorbed to the semiconductor layer 113. In certain embodiments, the photoelectrode 111 may be formed of transparent conducting oxide (TCO), such as indium tin oxide (ITO), fluorine tin oxide (FTO), or antimony tin oxide (ATO), which has electric conductivity and transparency. In certain embodiments, the dye molecules may include at least one component selected from the group consisting of Ru metallic compounds, 2,2-bipyridine derivatives, 2,2-bipyridine-4,4′ dicarboxylic acid derivatives, —NCS ligands, and terpyridine derivatives. In certain embodiments, the dye molecules may be Ru metallic compounds. In certain embodiments, the dye molecules may be 2,2-bipyridine derivatives. In certain embodiments, the dye molecules may be 2,2-bipyridine-4,4′ dicarboxylic acid derivatives. In certain embodiments, the dye molecules may be —NCS ligands. In certain embodiments, the dye molecules may be terpyridine derivatives.

In certain embodiments, the photoelectrode 111 formed of a transparent material may have high light transmission, and thus, sun light easily reaches the dye molecules of the semiconductor layer 113 where efficiency is decreased due to high electrical resistance. In certain embodiments, a grid electrode (not shown) may be further formed to compensate for high electric resistance of the photoelectrode 111. In certain embodiments, the grid electrode may include a metal, such as gold (Ag), silver (Au), or aluminum (Al), which has excellent electric conductivity. Since the electrical resistance of the grid electrode is much lower compared to that of a photoelectrode, a current may smoothly move. In certain embodiments, the grid electrode may have any of various patterns, such as a comb pattern and a lattice pattern.

In certain embodiments, the semiconductor layer 113 may include a semiconductor material or metal oxide that was used as the dye-sensitized solar cell. For example, the semiconductor layer 113 may include cadmium (Cd), zinc (Zn), indium (In), lead (Pb), molybdenum (Mo), tungsten (W), antimony (Sb), titanium (Ti), silver (Ag), manganese (Mn), tin (Sn) zirconium (Zr), strontium (Sr), gallium (Ga), silicon (Si), or chromium (Cr). In certain embodiments, the semiconductor layer 113 may increase photoelectric conversion efficiency by adsorbing the dye molecules. For example, the semiconductor layer 113 may be formed by coating a paste including semiconductor particles having a diameter of 5 nm to 1000 nm on the first substrate 110 on which the photoelectrode 111 is formed and applying predetermined heat or pressure.

In certain embodiments, the dye molecules absorbs light in the visible spectrum, and may be formed of molecules that quickly move electrons from a light excited state to the semiconductor layer 113. In certain embodiments, the dye molecules may be in any one of a liquid state, a gel state, and a solid state.

In certain embodiments, the scattering layer 117 may be formed on the semiconductor layer 113, and light incident toward the scattering layer 117 scatters light toward the semiconductor layer 113. In certain embodiments, the scattered light may be absorbed to the dye molecules chemically adsorbed to the semiconductor layer 113 to be used for photoelectric conversion.

In certain embodiments, the counter electrode 121 operates as a positive electrode of the dye-sensitized solar cell. In certain embodiments, the dye molecules adsorbed to the semiconductor layer 113 may be excited by absorbing light, and excited electrons are externally extracted through the photoelectrode 111. In certain embodiments, the dye molecules that lose electrons may be reduced by receiving electrons provided via oxidation of the electrolyte 140. In certain embodiments, the oxidized electrolyte 140 may be reduced by electrons that reached the counter electrode 121 through an external circuit, and thus, operation of photoelectric conversion is completed.

In certain embodiments, the counter electrode 121 may be formed of TCO, such as indium tin oxide (ITO), fluorine tin oxide (FTO), or antimony tin oxide (ATO), having electric conductivity and transparency. In certain embodiments, the counter electrode 121 and photoelectrode 111 may be formed of TCO having electric conductivity and transparency. Although not illustrated, the counter electrode 121 may further include a grid electrode having excellent electric conductivity formed of Ag, Au, or Al. Also, the grid electrode may have a comb pattern or lattice pattern to reduce electrical resistance of the counter electrode 121.

In certain embodiments, the catalyst layer 123 may include a metal, such as platinum (Pt), Au, Ag, or Al, a metal oxide, such as tin oxide, or a carbon-based material, such as graphite. The catalyst layer 123 operates as a reduction catalyst by receiving electrons from the external circuit.

In certain embodiments, the sun light incident through the photoelectrode 111 may be reflected when a metal thin film, such as a platinum thin film, is deposited as the catalyst layer 123. When a metal thin film, such as a platinum thin film, is deposited as the catalyst layer 123, reflected sun light may be incident on the semiconductor layer 113 to be used for photoelectric conversion, and thus, the photoelectric conversion efficiency may be further increased.

In certain embodiments, the second region A2 may include the first and second substrates 110 and 120 facing each other, the photoelectrode 111 and the counter electrode 121 respectively formed on the first and second substrates 110 and 120, and the electrolyte 140 disposed between the photoelectrode 111 and the counter electrode 121. As described above, the first and second substrates 110 and 120 may include a transparent material, and the photoelectrode 111 and the counter electrode 121 may be formed of TCO having electric conductivity and transparency.

Since the second region A2 does not include the semiconductor layer 113, the scattering layer 117, and the catalyst layer 123, the second region A1 may have higher light transmittance than the first region A1. Accordingly, light incident on the second region A2 may be absorbed by the dye molecules adsorbed to the semiconductor layer 113.

In certain embodiments, the second region A2 may be disposed at the center of the photoelectric cell S. For example, by disposing the first region A1 at two sides with the second region A2 as the center, the light incident on the second region A2 may be used by both the first region A1 on the left and the first region A1 on the right.

As a comparative example (not shown), if the second region A2 is disposed on one side and the first region A1 is disposed on another side of the photoelectric cell S, even if the same amount of light is incident through the second region A2, an amount of light used for photoelectric conversion by the first region A1 is smaller compared to the case when the first region A1 is disposed on both sides of the second region A2. As such, since the dye-sensitized solar cell according to the present embodiments include the first region A1 on two sides with the second region A2 as the center, light utilization rate may be improved.

FIG. 4 is a lateral cross-sectional view schematically illustrating a dye-sensitized solar cell according to another aspect of the present embodiments.

Referring to FIG. 4, the dye-sensitized solar cell according to the present embodiments also includes a photoelectric cell S defined by first and second substrates 410 and 420 disposed to face each other, and a sealing material 430, and includes first and second regions A1 and A2. Also, the photoelectric cell S includes a first region A1′ where photoelectric conversion is performed, and a second region A2′ having higher transparency than the first region A1′.

The first region A1′ includes a photoelectrode 411 and a counter electrode 421 respectively formed on the first and second substrates 410 and 420, and a semiconductor layer 413 to which dye molecules are adsorbed on the photoelectrode 411. A scattering layer 417 that scatters light penetrated through the semiconductor layer 413 is disposed on the semiconductor layer 413 to reuse light, and a catalyst layer 423 may be disposed on the counter electrode 421. The catalyst layer 423 increases a light utilization rate by reflecting light that penetrated through the scattering layer 417.

The second region A2 may be high transparency by not including the photoelectrode 411 and the counter electrode 421 on the first and second substrates 410 and 420.

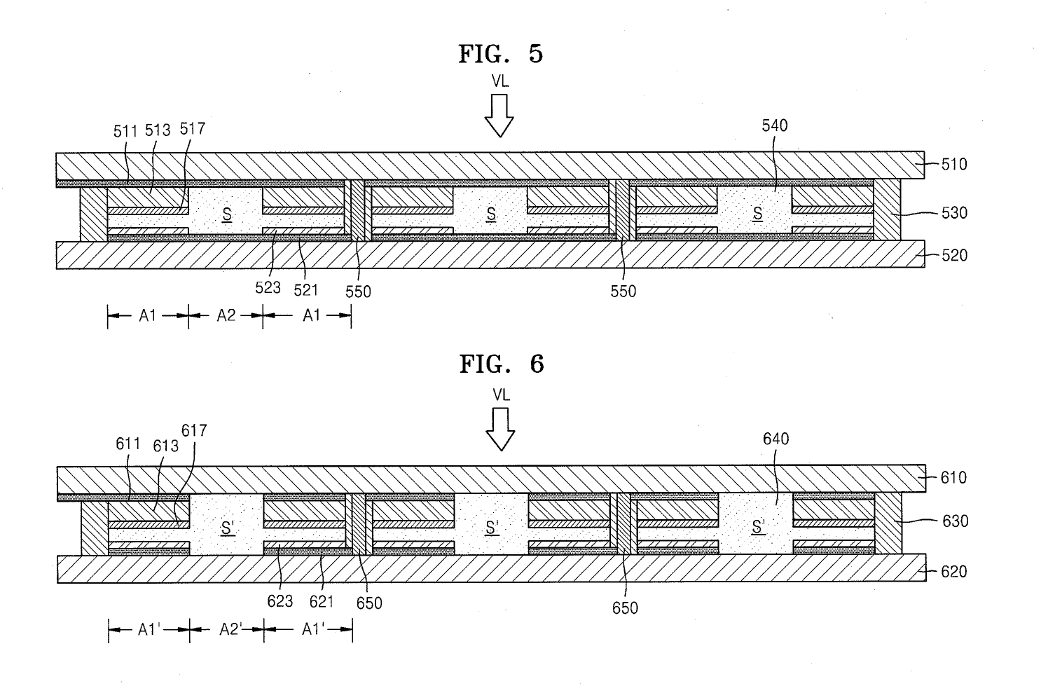

FIGS. 5 and 6 are lateral cross-sectional views of dye-sensitized solar cells according to an aspect of the present embodiments, wherein a plurality of cells are electrically connected to each other.

Referring to FIGS. 5 and 6, the dye-sensitized solar cell may include a plurality of photoelectric cells S and S′ that are electrically connected to each other. Sealing materials 530 and 630 disposed between first and second substrates 510 and 520 and 610 and 620 not only seal electrolytes 540 and 640, but also define the photoelectric cells S and S′. The neighboring photoelectric cells S and S′ may be electrically connected via connecting units 550 and 650.

Each of the photoelectric cells S shown in FIG. 5 includes a first region A1 and a second region A2 that are spatially integrated. The first region A1 includes a photoelectrode 511, a semiconductor layer 513, a scattering layer 517, a counter electrode 521, a catalyst layer 523, and an electrolyte 540, whereas the second region A2 only includes the photoelectrode 511, the counter electrode 521, and the electrolyte 540. Thus, the transparency of the second region A2 may be higher than that of the first region A1. Detailed structures of the first and second regions A1 and A2 are as described above with reference to FIGS. 1 through 3.

Each of the photoelectric cells S′ shown in FIG. 6 also includes a first region A1′ and a second region A2′ that are spatially integrated. The first region A1′ includes a photoelectrode 611, a semiconductor layer 613, a scattering layer 617, a counter electrode 621, a catalyst layer 623, and an electrolyte 640, whereas the second region A2′ only includes the electrolyte 640 disposed between the first and second substrates 610 and 620. Thus, the transparency of the second region A2′ may be higher than that of the first region A1′. Detailed structures of the first and second regions A1′ and A2′ are as described above with reference to FIG. 4.

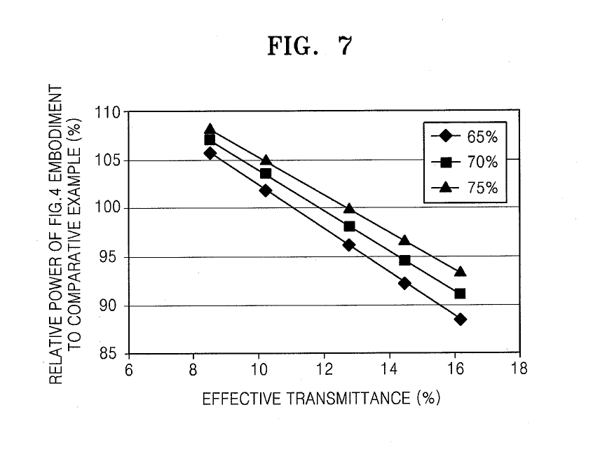

FIG. 7 is a graph of relative power to effective transmittance for comparing a dye-sensitized solar cell according to an embodiment of the present invention and a dye-sensitized solar cell according to a comparative example. In FIG. 7, each of 65%, 70%, and 75% shows an aperture ratio, i.e., an area of a photoelectric cell to an overall area of a dye-sensitized solar cell.

In FIG. 7, the dye-sensitized solar cell according to the present embodiments is identical to that of FIG. 4, and the dye-sensitized solar cell according to the comparative example includes the photoelectric cell having the same size as that in FIG. 4 but does not include a first region in the photoelectric cell. In other words, the photoelectric cell of the comparative example has the same structure as described with reference to a second region.

Referring to FIG. 7, when an effective ratio of a dye-sensitized solar cell is equal to or smaller than 10%, the efficiency of the dye-sensitized solar cell of the current embodiment is higher by about 5% to 8% than that of the dye-sensitized solar cell of the comparative example.

A relative power is increased as an aperture ratio is increased. For example, when the aperture ratio is about 85%, the efficiency may be maximized when a ratio of an area of the first region to an area of the second region in the dye-sensitized solar cell of the current embodiment is about 1.4:3.7.

As described above, according to the one or more of the above aspects of the present embodiments, a light utilization rate can be improved by configuring a photoelectric cell to include a first region where photoelectric conversion is performed and a second region having higher transparency than the first region.

Also, light can be reused by disposing a scattering layer on a semiconductor layer that adsorbs dye molecules, and a reflective catalyst layer on a counter electrode, and thus a light utilization rate can be improved.

It should be understood that the exemplary embodiments described therein should be considered in a descriptive sense only and not for purposes of limitation. Descriptions of features or aspects within each embodiment should typically be considered as available for other similar features or aspects in other embodiments.

What is claimed is:

1. A dye-sensitized solar cell comprising:
first and second substrates disposed to face each other; and
a sealing material disposed between the first and second substrates and defining at least one photoelectric cell that performs photoelectric conversion,
wherein the photoelectric cell comprises:
a first region; and
a second region connected to the first region and having higher transparency than the first region,
wherein the first region performs photoelectric conversion using incident light through the first region and incident light through the second region.

2. The dye-sensitized solar cell of claim 1, wherein the first region comprises:
first and second electrodes respectively disposed on inner sides of the first and second substrates;
a semiconductor layer disposed on the first electrode and adsorbing dye molecules;
a scattering layer disposed on the semiconductor layer and scattering light that passed through the semiconductor layer toward the semiconductor layer; and
an electrolyte disposed between the scattering layer and the second electrode.

3. The dye-sensitized solar cell of claim 2, wherein the first region further comprises a catalyst layer disposed on the second electrode.

4. The dye-sensitized solar cell of claim 3, wherein the catalyst layer is configured to reflect light that passes through the scattering layer.

5. The dye-sensitized solar cell of claim 1, wherein the second region comprises an electrolyte disposed between the first and second substrates.

6. The dye-sensitized solar cell of claim 5, wherein the second region further comprises:
a first transparent electrode disposed between the first substrate and the electrolyte; and
a second transparent electrode disposed between the second substrate and the electrolyte.

7. The dye-sensitized solar cell of claim 1, wherein the first region is disposed at two sides of the second region.

8. The dye-sensitized solar cell of claim 1, wherein the first region and the second region are spatially connected to each other.

9. The dye-sensitized solar cell of claim 8, further comprising an electrolyte wherein the first region and the second region are fluidally connected to each other through the electrolyte.

10. A dye-sensitized solar cell comprising:
first and second substrates disposed to face each other; and
a sealing member disposed between the first and second substrates to define at least one photoelectric cell that performs photoelectric conversion, and sealing an electrolyte accommodated in the at least one photoelectric cell,
wherein the at least one photoelectric cell comprises:
a first region comprising first and second electrodes respectively disposed on inner sides of the first and second substrates, and a semiconductor layer disposed on the first electrode and adsorbing dye molecules; and
a second region connected to the first region and having higher transparency than the first region,
wherein the first region performs photoelectric conversion using incident light through the first region and incident light through the second region.

11. The dye-sensitized solar cell of claim 10, wherein the first region further comprises a scattering layer disposed on the semiconductor layer which is configured to scatter light that passes through the semiconductor layer toward the semiconductor layer.

12. The dye-sensitized solar cell of claim 11, wherein the second region does not comprise the semiconductor layer and the scattering layer.

13. The dye-sensitized solar cell of claim 10, wherein the second region comprises the electrolyte disposed between the first substrate and the second substrate.

14. The dye-sensitized solar cell of claim 13, wherein the second region further comprises:
the first electrode disposed between the first substrate and the electrolyte; and
the second electrode disposed between the second substrate and the electrolyte.

15. The dye-sensitized solar cell of claim 10, wherein the first region further comprises a catalyst layer disposed on the second electrode.

16. The dye-sensitized solar cell of claim 15, wherein the catalyst layer comprises a metal thin film configured to reflect light that passes through the scattering layer.

17. The dye-sensitized solar cell of claim 10, wherein the first region and the second region are spatially connected to each other.

18. The dye-sensitized solar cell of claim 10, wherein the first region is disposed at two sides of the second region.

19. The dye-sensitized solar cell of claim 1, wherein the first and second substrates each have an approximate rectangular shape.

20. The dye-sensitized solar cell of claim 2, wherein the adsorbing dye molecules include at least one component selected from the group consisting of Ru metallic compounds, 2,2-bipyridine derivatives, 2,2-bipyridine-4,4′ dicarboxylic acid derivatives, —NCS ligands, and terpyridine derivatives.
